(19) United States
(12) Patent Application Publication
(10) Pub. No.: US 2026/0090079 A1
(43) Pub. Date: Mar. 26, 2026

(54) Low Noise Stacked Field Effect Transistor Design

(71) Applicant: Apple Inc., Cupertino, CA (US)

(72) Inventor: Domagoj Siprak, Munich (DE)

(21) Appl. No.: 19/336,156

(22) Filed: Sep. 22, 2025

Related U.S. Application Data
(60) Provisional application No. 63/697,682, filed on Sep. 23, 2024.

(51) Int. Cl. H10D 84/83; H03F 3/16; H10D 30/60

(52) U.S. Cl. CPC H10D 84/83125; H10D 30/605; H03F 3/16; H03F 2200/294

(57) ABSTRACT

A low-noise amplifier structure utilizing horizontally stacked field-effect transistors (FETs) is described. The stacked FET structure includes two FETs stacked horizontally and connected in series (e.g., with a shared source/drain region). The stacked FET structure described a pitch between gates that is increased above a minimum pitch defined for a transistor region of the device. Increasing the pitch reduces a metallurgical channel length of a second FET in the stacked structure below what the metallurgical channel length would be at the minimum pitch. Reducing the metallurgical channel length improves the signal-to-noise ratio of the low-noise amplifier structure.

### PRIORITY CLAIM

The present application claims priority to U.S. Provisional App. No. 63/697,682, entitled “Low Noise Stacked Field Effect Transistor Design,” filed Sep. 23, 2024, the disclosure of which is incorporated by reference herein in its entirety.

### BACKGROUND

### Technical Field

Embodiments described herein relate to low noise amplifiers for semiconductor devices. More particularly, embodiments described herein relate to implementation of low noise amplifiers using stacked field-effect transistors (FETs).

### Description of the Related Art

Low noise amplifiers (LNAs) are used in a variety of devices that process analog signals such as radio frequency (RF) signals. For instance, many wireless devices use LNAs to improve signal-to-noise ratios in RF antenna signals in order for the signals to be further processed. With the low power of antenna signals in wireless devices, it's important for the LNAs to boost the RF signals without oscillations and while minimizing any addition of noise to the signals. The RF signals may then be converted to digital signals (e.g., by analog-to-digital converter circuits) and processed as digital signals. Thus, any improvements in signal amplification by the LNAs serves to increase the spatial distance of the transmission between transmitter and receiver and improve the accuracy of digital signal processing by wireless devices. For instance, improvements in the bit error rate may be generated through low noise signal amplification by the LNAs.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a cross-sectional side-view representation of an embodiment of a low noise amplifier active device with horizontally stacked FETs, according to some embodiments.

FIG. 2 depicts a side-view representation of an embodiment of a low noise amplifier active device with horizontally stacked FETs at a greater pitch, according to some embodiments.

FIG. 3 depicts a side-view representation of an embodiment of a low noise amplifier with horizontally stacked FETs at a greater pitch and increased gate length, according to some embodiments.

FIG. 4 is a top view representation of a low noise amplifier active device showing channel width per gate finger, according to some embodiments.

FIG. 5A depicts a side-view representation of a low noise amplifier active device with two horizontally stacked FETs connected in parallel on a substrate, according to some embodiments.

FIG. 5B depicts a cross-sectional side-view representation of an FET showing geometrical dimensions referred to in Table I.

FIG. 6 is a block diagram of one embodiment of an example signal processing system.

FIG. 7 is a cross-sectional side-view representation of beginning manufacturing steps of an LNA (low noise amplifier) active device with horizontally stacked FETs on a substrate, according to some embodiments.

FIG. 8 is a cross-sectional side-view representation of a next manufacturing step of an LNA active device with horizontally stacked FETs on a substrate, according to some embodiments.

FIG. 9 is a cross-sectional side-view representation of a manufacturing step to form gate spacers for an LNA active device with horizontally stacked FETs on a substrate, according to some embodiments.

FIG. 10 is a cross-sectional side-view representation of a next doping step for an LNA active device with horizontally stacked FETs on a substrate, according to some embodiments.

FIG. 11 is a cross-sectional side-view representation of a later manufacturing step for an LNA active device with horizontally stacked FETs on a substrate, according to some embodiments.

FIG. 12 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to implementations of low noise stacked field-effect transistor (FET) amplifier devices. As described herein, low noise amplifiers (LNAs) are used in a variety of devices to boost RF signal while minimizing the addition of noise to the signals. For instance, wireless devices or mobile devices implement LNAs to improve received RF signals before converting the RF signals to digital signals and digital processing of the signals. One type of LNA structure often used in such devices is a horizontally stacked FET. A stacked FET structure includes two FETs stacked horizontally over a substrate and connected (e.g., electrically connected) in series.

Certain implementations of stacked FET structures have the gate materials (e.g., the gate metals, silicide doped polysilicon gates, and gate conductors) of the stacked transistors placed at a minimum pitch (e.g., minimum poly pitch) defined for a transistor region of the substrate on which the FET structures are being formed. A length of a gate can be defined as a length of the gate material over the channel region. The channel region under the gate has a metallurgical channel length defined as a distance between a doping region on a first side of the channel region and a doping region on a second side of the channel region. For transistors, it is known that the metallurgical channel length for the transistors are less than the gate length. Some stacked FETs or single FETs may be implemented with increased poly pitch above the minimum pitch. Typically, however, engineering effort is put into achieving a same minimum gate length and a same metallurgical channel length as for (normal) digital transistors at the minimum poly pitch. Stacked FETs with increased poly pitch may be implemented, for example, to reduce the coupling capacitance between a gate material and a gate material. Single FETs with increased poly pitch may be implemented in power amplifier transistors to mitigate electromigration reliability risks by allowing wider metals for the drain and the source. These efforts for stacked FETs and single FETs with increased poly pitch attempt to achieve the same minimum metallurgical channel length as in all other transistors and are driven from a digital point of view. The present disclosure recognizes, however, that in certain increased pitch, low noise stacked FETs, the metallurgical channel length may be less than the metallurgical channel length in the other FETs to provide certain advantages by deviating from the digital view driven approach that tries to make the gate length and metallurgical channel length in increased poly pitch transistors the same as in transistors used for digital applications.

For instance, while the above-described stacked FET structures can operate as LNAs that provide signal boost and minimal noise addition, the present inventor has recognized that additional improvements may be made in low noise signal amplification by stacked FET structures through some variations in the design of the stacked FET structures. In certain contemplated embodiments, the pitch between the gate materials of the stacked transistors is placed at a pitch above the minimum pitch. Increasing the pitch between gate materials may reduce the metallurgical channel length for the second transistor in the stack, as described herein. In some embodiments, the metallurgical channel length for the first transistor in the stack is also reduced. This reduction in metallurgical channel length may improve signal-to-noise ratio of the stacked FET structure compared to stacked FET structures with gate materials at the minimum pitch. Further improvements in the signal-to-noise ratio may also be achieved by adjustment in other design properties in the stacked FET structures, as described herein.

Certain embodiments disclosed herein have three broad elements: 1) a first FET formed in a transistor region above a substrate; 2) a second FET formed in the transistor region where a gate material of the second FET is at a pitch relative to a gate material of the first FET that is greater than a minimum pitch for the transistor region, and 3) a metallurgical channel length for a second channel region under the second gate material is less than the metallurgical channel length would be when the gate material of the second FET is at the minimum pitch relative to the gate material of the first FET. The metallurgical channel length may decrease due to an increase in lateral diffusion (e.g., width of diffusion) of the doping extension regions under the gates between the extension doping regions in the channel region when the gate materials are above the minimum pitch. In certain embodiments, a metallurgical channel length in a channel region is defined as a horizontal distance between a doping region on one side of the channel region and a doping region on another side of the channel region. For channel regions with doping extension regions, the metallurgical channel length is the distance between the doping extension regions, as described herein. In various embodiments, the first FET and the second FET are stacked horizontally above the substrate with the FETs being electrically connected in series. In some embodiments, the first FET and the second FET share a doping region (e.g., a source region of the first FET is a drain region of the second FET).

While the metallurgical channel length may be defined according to the spacing (e.g., horizontal distance) between extension regions as described above, additional methods for defining the metallurgical channel length may be contemplated based on dopant concentration gradients in the channel region. For instance, source and drain regions typically do not have sharp, well-defined dopant concentrations that define the borders of the regions but rather have concentration gradients associated with the diffusion of the dopants (e.g., due to annealing). Values of dopant concentrations may, however, still be implemented for defining the metallurgical channel length by, for example, specifying certain values of the dopant concentrations to define the edges of the metallurgical channel. To begin, the middle of the channel region may have a dopant concentration that is zero or near zero (e.g., negligible impact to the total resistance of the channel region). As the position moves away from the middle of the channel region towards the doping regions and extension regions, the dopant concentration will increase. Accordingly, specified threshold values may be set (e.g., specified values of the dopant concentration) that define the edges (e.g., borders) of the metallurgical channel region. Thus, the metallurgical channel length may be defined as the distance between these edges determined by the dopant concentration satisfying the specified threshold values for the dopant concentration.

As is known, the type of dopant in the source and drain regions (e.g., n-type dopants for NFET) is different from the dopants in the channel region (e.g., no dopants in case of FinFET, FDSOI (Fully Depleted Silicon on Insulator), or p-type dopants for planar NFET) and from the dopants in the extension regions (n-type dopants for NFET). Accordingly, the dopant concentration for the specified threshold values may also be agnostic to the type of dopant and be based on the absolute value of the dopant concentration.

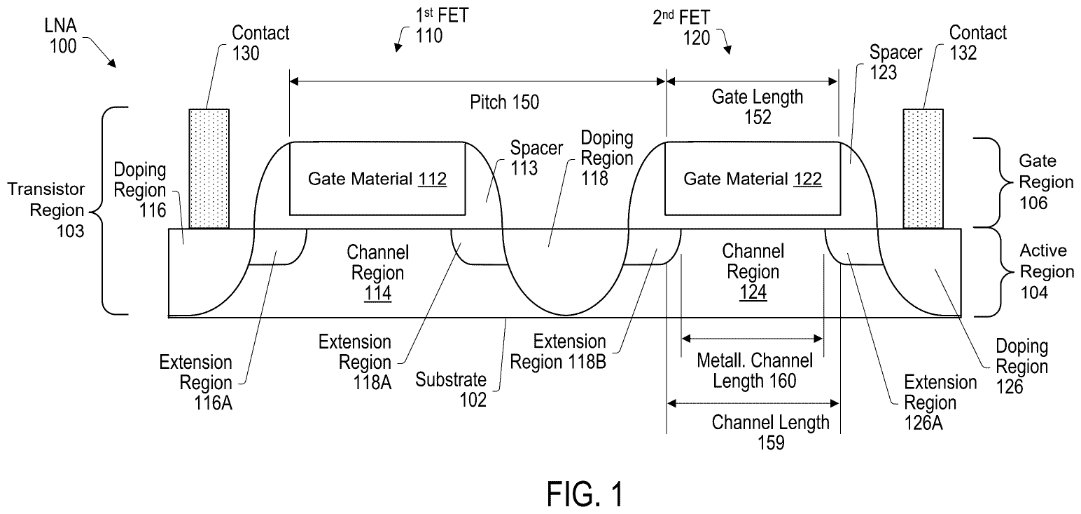

FIG. 1 depicts a side-view representation of an embodiment of a low noise amplifier with horizontally stacked FETs, according to some embodiments. In the illustrated embodiment, LNA 100 includes first FET 110 and second FET 120 stacked horizontally on substrate 102. First FET 110 and second FET 120 may be formed in transistor region 103 of substrate 102 that includes active region 104 in the substrate and gate region 106 vertically above the active region and the substrate.

In certain embodiments, first FET 110 includes gate material 112 in gate region 106 above channel region 114 in active region 104. In some embodiments, gate material 112 is surrounded by gate spacer 113 above substrate 102. Channel region 114 is a region formed between doping region 116 on a first side of the channel region and doping region 118 on a second side of the channel region. In various embodiments, doping region 116 includes extension region 116A and doping region 118 includes extension region 118A. Extension region 116A and extension region 118A may be formed as regions with different doping concentrations, different doping depths in the active region, and different dopant species (e.g., doping material) from doping region 116 and doping region 118, respectively, in channel region 114 to effect changes in the electric field of the channel region along with drain and source access resistance to the channel region. For instance, in some embodiments, extension region 116A and extension region 118A may be lightly doped drain (LDD) extension regions that reduce hot carrier effects in channel region 114. In some embodiments, extension region 116A and extension region 118A (along with extension region 118B and extension region 126A, described below), may be highly doped drain extensions (HDD) that provide low access resistance to the channel region. Channel lengths (such as metallurgical channel length, described below) are typically measured between as lengths between extension regions.

As shown in FIG. 1, second FET 120 includes gate material 122 in gate region 106 above channel region 124 in active region 104. Gate material 122 is surrounded by gate spacer 123 above substrate 102. Channel region 124 is a region formed between doping region 118 on a first side of the channel region and doping region 126 on a second side of the channel region. Doping region 118 includes extension region 118B on the first side of channel region 124 and doping region 126 includes extension region 126A on the second side of the channel region. In certain embodiments, doping region 118 is shared between first FET 110 and second FET 120. For instance, doping region may be a shared doping region operating as a source for first FET 110 and a drain for the second FET 120.

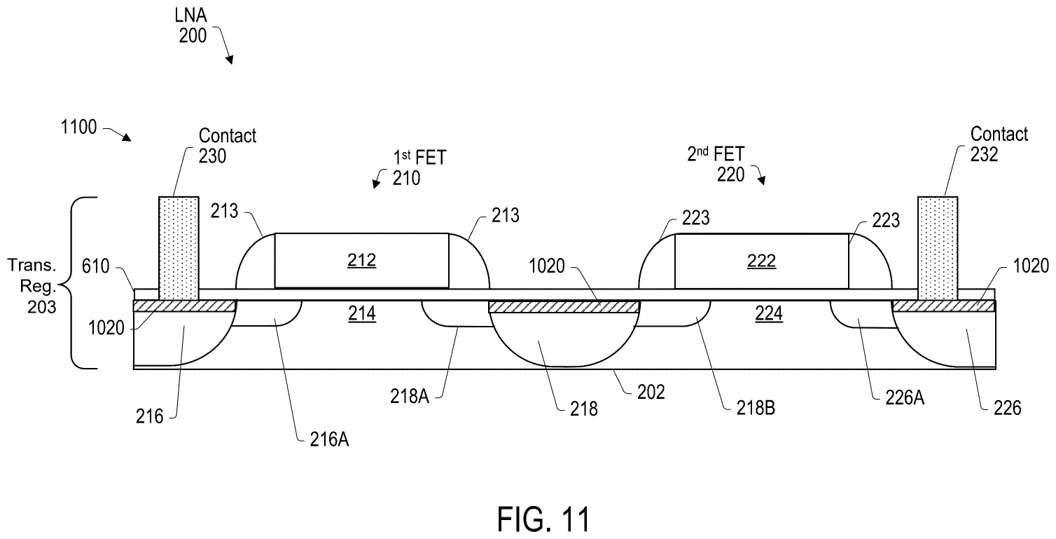

In various embodiments, contact 130 may be formed to connect to doping region 116 and contact 132 may be formed to connect to doping region 126. In some embodiments, a silicide region (shown in FIGS. 10 and 11) is formed in doped regions 116, 118, and 126 before forming contact 130 and contact 132. Contact 130 and contact 132 may be implemented, along with contacts to gate material 112 and gate material 122, to provide operational connections for low noise amplification by LNA 100. In various embodiments, contacts 130, 132 and the contacts to gate material 112 and gate material 122 are made of tungsten or another conductive material. In certain embodiments, drain doping region 116 of first FET 110 is the drain of the stacked FET and thus coupled to a power supply node (e.g., VDD) of an LNA circuit. In some embodiments, the drain of the stacked FET is connected to the power supply node through a load (such as a coil, a transformer, an inductor, a resistor, or a PMOS FET). Source doping region 126 of second FET 120 may be the source of the stacked FET and coupled to a ground node of the LNA circuit. In some embodiments, an inductor or other device to set the input impedance of the LNA towards the antenna impedance is coupled between the source of the stacked FET and the ground node of the LNA circuit.

In the illustrated embodiment of FIG. 1, second FET 120 is placed relative to first FET 110 with gate material 122 at pitch 150 from gate material 112. In certain embodiments, pitch 150 is a minimum pitch defined for transistor region 103. For instance, pitch 150 may be a minimum pitch defined based on the lithography process implemented to form the logic in transistor region 103. In some embodiments, pitch 150 is referred to as a minimum contacted-poly pitch (CPP). Pitch 150 defines the minimum distance (e.g., spacing) at which a first side of gate material 122 can be placed relative to a first side of gate material 112 for each gate length and the minimum pitch of the technology is achieved for the smallest gate length of the technology.

As shown in FIG. 1, gate material 122 has a gate length 152 and channel region 124 has channel length 159. Gate length 152 is essentially the length (in the direction from left to right in illustration) of gate material 122. Channel length 159 is the length in channel region 124 that corresponds to gate length 152 (e.g., channel length 159 and gate length 152 are approximately the same length). Channel region 124 may, however, have an effective channel length that is reduced due to the presence of extension region 118B and extension region 126A. For instance, extension region 118B and extension region 126A may have portions that extend under gate material 122 due to lateral diffusion. These lateral diffusion portions extending under gate material 122 effectively reduce (e.g., shorten) the length of channel region 124. This reduced length may be referred to as metallurgical channel length 160 and, with the presence of the portions of extension region 118B and extension region 126A under gate material 122, the metallurgical channel length is less than gate length 152 and channel length 159 for second FET 120.

FIG. 1 depicts an illustration of an embodiment of LNA 100 where second FET 120 is placed at its minimum distance (e.g., minimum spacing) from first FET 110 (e.g., pitch 150 is the minimum pitch between the gates of the FETs). While many circuit designs lean towards the placement of FETs at minimum distances, the present disclosure recognizes that various electrical properties of a low noise amplifier (LNA) with horizontally stacked FETs may be improved by slightly increasing the distance between the FETs. In certain instances, the improvement in electrical properties may overtake any disadvantages caused by the increased spacing between the FETs (such as larger FET area, lower FET yield, or any processing constraints). Slightly increasing the distance (e.g., spacing) between FETs (e.g., gates of the FETs) may be relatively easy to implement with small changes in the lithography process (e.g., by changing patterns in optical masks for fabricating the FETs). The larger pitch generated by increasing the distance between gate material 112 and gate material 122 may lead to increased lateral diffusion of the extension regions under the gate material and a decrease in the metallurgical channel length.

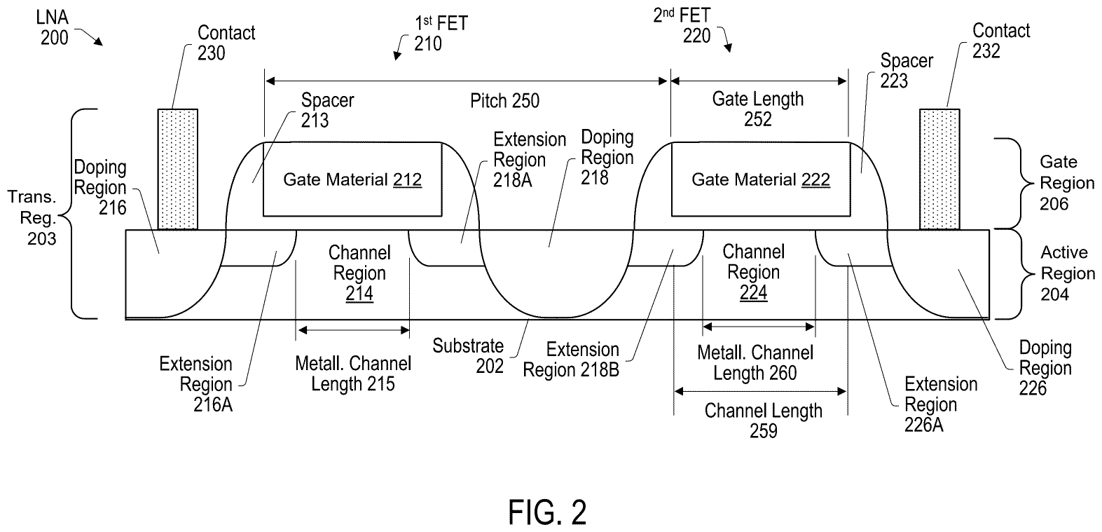

FIG. 2 depicts a side-view representation of an embodiment of a low noise amplifier with horizontally stacked FETs at a greater pitch, according to some embodiments. In the illustrated embodiment, LNA 200 includes first FET 210 and second FET 220 stacked horizontally on substrate 202. First FET 210 and second FET 220 may be formed in transistor region 203 of substrate 202 that includes active region 204 in the substrate and gate region 206 vertically above the active region and the substrate.

In various embodiments, first FET 210 includes gate material 212 in gate region 206 and channel region 214 is in active region 204 below the gate material. Gate material 212 may be surrounded by gate spacer 213 above substrate 202. In certain embodiments, channel region 214 is a region formed between doping region 216 on a first side of the channel region and doping region 218 on a second side of the channel region. In some embodiments, doping region 216 is a drain region for first FET 210 and doping region 218 is a source region for the first FET.

In the illustrated embodiment, doping region 216 includes extension region 216A and doping region 218 includes extension region 218A. Extension region 216A and extension region 218A may be formed as regions with different doping concentrations, different doping depths in the active region, and different dopant species from doping region 216 (e.g., arsenic (As) or antimony (Sb) as doping material) and doping region 218 (e.g., phosphorus (P) as doping material), respectively. Forming extension region 216A and extension region 218A with different doping concentrations, doping depths, or dopant species may affect changes in the electric field of channel region 214 and drain and source access resistance to the channel region, as described herein.

In some embodiments, extension region 216A and extension region 218A (along with extension region 218B and extension region 226A, described below) may be highly doped drain extensions (HDD) that provide low access resistance to the channel region. In certain instances, to achieve a high signal-to-noise ratio in the low noise stacked FET device, it is necessary to provide a low access resistance to the source of second FET 220 that is connected towards the ground node of the LNA circuit. Accordingly, in certain embodiments, a selective higher dosage implant of the source extension implant (e.g., extension region 226A) or the source implant (e.g., doping region 226) reduces the source access resistance to the channel region of second FET 220 and improves the signal-to-noise ratio of the low noise stacked FET device. First FET 210 may have metallurgical channel length 215 in channel region 214 that is defined as the length between extension region 216A and extension region 218A.

Turning to second FET 220, the second FET includes gate material 222 in gate region 206 above channel region 224 in active region 204 with the gate material surrounded by gate spacer 223 above substrate 202. Channel region 224 of second FET 220 is a region formed between doping region 218 on a first side of the channel region and doping region 226 on a second side of the channel region. In certain embodiments, doping region 218 is a drain region for second FET 220 and doping region 226 is a source region for the second FET. In some embodiments, doping region 218 is a shared doping region with the doping region shared between first FET 210 and second FET 220. For instance, doping region 218 may be a source region for first FET 210 that is shared as a drain region for second FET 220.

In various embodiments, contact 230 may be formed to connect to doping region 216 and contact 232 may be formed to connect to doping region 226. Contact 230 and contact 232 may be implemented, along with contacts to gate material 212 and gate material 222, to provide operational connections for low noise amplification by LNA 200. In some embodiments, a silicide region (shown in FIGS. 10 and 11) is formed in doped regions 216, 218, and 226 before forming contact 230 and contact 232. In various embodiments, contacts 230, 232 and the contacts to gate material 212 and gate material 222 are made of tungsten or another conductive material. In certain embodiments, drain doping region 216 of first FET 210 is the drain of the stacked FET and thus coupled to a power supply node (e.g., VDD) of an LNA circuit. Source doping region 226 of second FET 220 may be the source of the stacked FET and coupled to a ground node of the LNA circuit.

In the illustrated embodiment of FIG. 2, gate material 222 in second FET 220 is placed at pitch 250 relative to gate material 212 in first FET 210. In certain embodiments, pitch 250 is greater than pitch 150 (shown in FIG. 1 and which is a minimum pitch defined for transistor region 103 or transistor region 203). While pitch 250 is greater than pitch 150, gate length 252 of gate material 222 is substantially equal to gate length 152 of gate material 122. Accordingly, while the length of the gate material in second FET 220 remains the same as the length of the gate material for second FET 120, the pitch between the gate materials is increased (e.g., pitch 250 is greater than pitch 150).

As shown in FIG. 2, doping region 218 includes extension region 218B on the first side of channel region 224 and doping region 226 includes extension region 226A on the second side of the channel region. Metallurgical channel length 260 is the length of channel region 224 between extension region 218B and extension region 226A. As may be seen by a comparison of FIG. 2 to FIG. 1, when the pitch between the gate materials is increased (e.g., pitch 250 is increased from pitch 150), the metallurgical channel length decreases (e.g., metallurgical channel length 260 is less than metallurgical channel length 160). Note that channel length 259 remains substantially the same as channel length 159 due to gate length 252 remaining substantially the same.

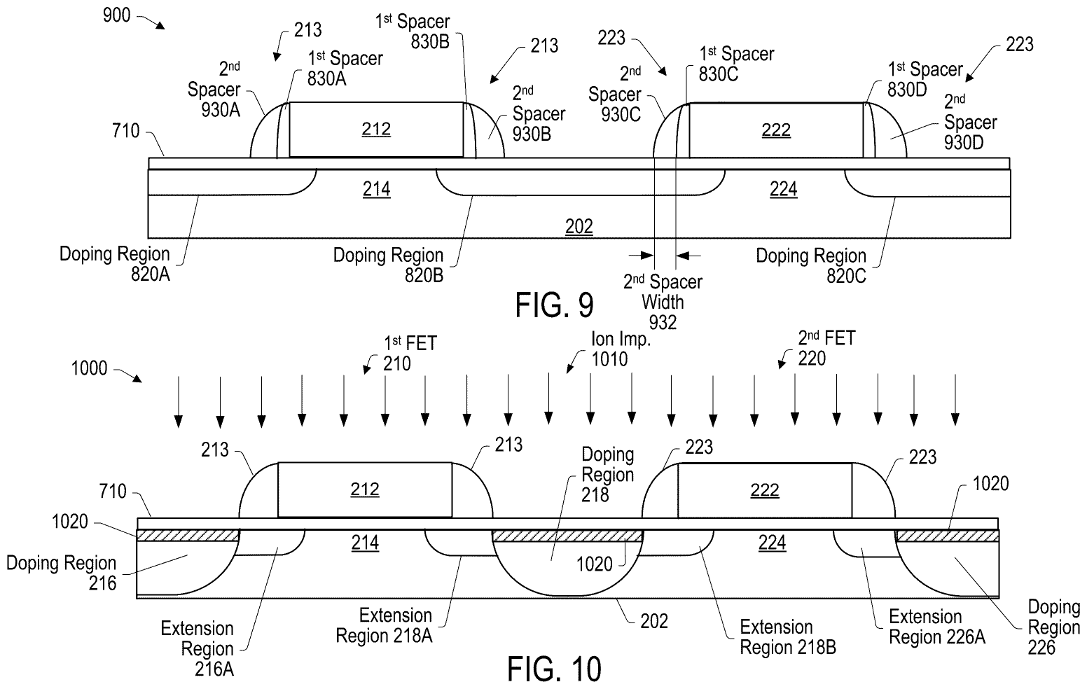

In various embodiments, the metallurgical channel length shortens because the length of the extension regions (e.g., lateral diffusion length of extension region 218B and extension region 226A) increases while gate length (e.g., gate length 252) is held substantially the same when pitch between the gates is increased. The increases in the length of the extension regions under gate material 222 may occur as a function of increased available amount of dopant in the region between the two gate materials with increased pitch by dopant diffusion during a thermal annealing step. For instance, it should be noted that the length of the extension regions of first FET 210 (e.g., extension region 216A and extension region 218A) also increase in FIG. 2 relative to the extension regions of first FET 110 (e.g., extension region 116A and extension region 118A), shown in FIG. 1. The amount of the increase in lateral diffusion of the extension regions under the gate materials may be controlled by forming first spacers (as part of spacer 213 and spacer 223) with a first width before forming the extension regions. Second spacers with second widths may be formed over the first spacers after forming the extension and before forming doping regions 216, 218, and 226 (e.g., the source and drain regions of the low noise stacked FET device that is electrically coupled, via contacts 230 and 232, to further parts of the LNA circuit). The use of first and second spacers during fabrication is described further below with respect to the embodiments depicted in FIGS. 8 and 9.

In certain embodiments, with metallurgical channel length 260 decreased, LNA 200 has improved signal-to-noise ratio versus LNA 100. The improved signal-to-noise ratio may be the result of the gate length of the second FET remaining constant, which gives a constant gate resistance, while the metallurgical channel length decreases in length. For instance, the following relationships may be given for signal power and noise power in relation to metallurgical channel length, Lgₘ, and gate length, Lgₚ:

$$Signal Power ∼ {g}_{m}^{2} ; \qquad ( 1 )$$

$$and$$

$$Noise Power ∼ {g}_{m}^{2} \times {R}_{g} + α \times {g}_{m} ; \qquad ( 2 )$$

where (gₘₓ²×R_{g}) is the gate resistance noise and (α×gₘ) is the channel
noise for a metal-oxide-semiconductor visible (e.g., measurable) at the drain (as
drain current noise), with transconductance, gₘ, and gate resistance, R_{g}.

With the relationships in Equations 1-2, the signal-to-noise ratio may be defined by the following relationship:

$$\frac{Signal}{Nois e} ∼ \frac{1}{{R}_{g} + α / {g}_{m}} . \qquad ( 3 )$$

The term a is a noise coefficient and the terms, gₘ and R_{g}, may be defined in terms of metallurgical channel length and gate length by the following relationships:

$${g}_{m} ∼ \frac{1}{L {g}_{m}} ; with {Lg}_{m} being the metallurgical channel length ; \qquad ( 4 )$$

$$and$$

$${R}_{g} ∼ \frac{1}{{Lg}_{p}} ; with {Lg}_{m} being the gate length of the gate material . \qquad ( 5 )$$

Accordingly, based on the relationship of Equations (3) and (4) above, when the gate length remains the same and the metallurgical channel length is reduced, the signal-to-noise ratio increases, since gₘ increases when the metallurgical channel length is reduced. In some embodiments, the increase in pitch (e.g., pitch 250, shown in FIG. 2) and the reduction in metallurgical channel length may be allowed in horizontally stacked FETs due to the reduced short channel effects from the extension regions and relaxed reliability requirements of stacked FET devices. In single FETs (e.g., NFET), the power supply voltage, Vdd, drops over a single FET while in the stacked FET the supply voltage drops over two FETs connected in electrical series. This effect reduces the voltage drop over each FET of the stacked FET and gives an increased reliability margin that allows reduction in the metallurgical gate length below the value for single FETs. The ability to increase the pitch and reduce the metallurgical channel length may also be dependent on a total gate length available for the LNA device. For a constant width of the first spacer (described above and in FIGS. 8 and 9) and a constant thermal budget during the anneal step, the lateral diffusion of extension regions under the gate covers an increasing percentage of the gate length as the gate length decreases. In some embodiments, the gate length of first FET 210 is different from the gate length of second FET 220 in LNA 200. For instance, second FET 220 may have a larger gate length compared to first FET 210 in technologies with strongly increased gate resistance. The gate resistance in first FET 210 is of less importance for the signal-to-noise ratio of the LNA device and thus can have a shorter gate length with a higher gate resistance while maintaining the desired signal-to-noise properties for the LNA device.

Additionally, based on the relationship of Equations (3) and (5) above, embodiments may be contemplated where the gate length is increased with a larger pitch while the metallurgical channel length remains the same. The metallurgical channel length may stay the same due to a larger lateral diffusion of the extensions under the gate induced by the larger pitch that compensates for the increase in gate length. In such embodiments, increasing the gate length reduces the gate resistance while the signal-to-noise ratio increases with the metallurgical channel length staying the same. Embodiments may be contemplated where the gate length is increased compared to LNA 100 of FIG. 1 or LNA 200 in FIG. 2 but the metallurgical channel length is as small as for the minimum pitch stacked FET of LNA 100 in FIG. 1 when having minimum gate length. Yet further embodiments may be contemplated where the metallurgical channel length is decreased to a value as in LNA 200 of FIG. 2 but the gate length is increased compared to the gate length in FIG. 2 to reduce the gate resistance and increase the signal-to-noise ratio.

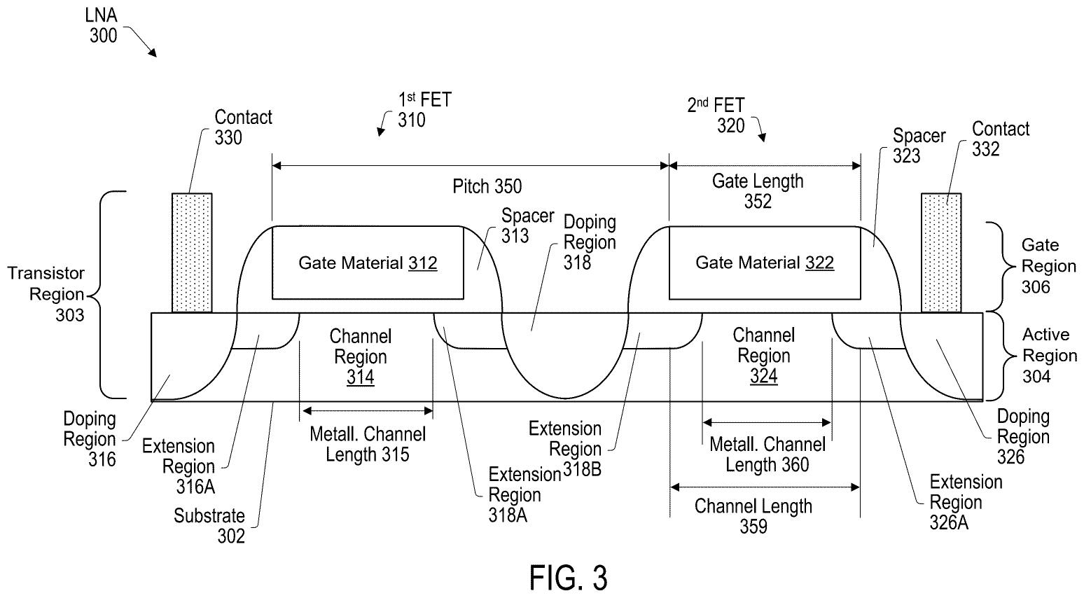

FIG. 3 depicts a side-view representation of an embodiment of a low noise amplifier with horizontally stacked FETs at a greater pitch and increased gate length, according to some embodiments. In the illustrated embodiment, LNA 300 includes first FET 310 and second FET 320 stacked horizontally on substrate 302. First FET 310 and second FET 320 may be formed in transistor region 303 of substrate 302 that includes active region 304 in the substrate and gate region 306 vertically above the active region and the substrate.

In various embodiments, first FET 310 includes gate material 312 in gate region 306 and channel region 314 is in active region 304 below the gate material. Gate material 312 may be surrounded by gate spacer 313 above substrate 302. In certain embodiments, channel region 314 is a region formed between doping region 316 on a first side of the channel region and doping region 318 on a second side of the channel region. In some embodiments, doping region 316 is a drain region for first FET 310 and doping region 318 is a source region for the first FET.

In certain embodiments, as described previously, doping region 316 includes extension region 316A and doping region 318 includes extension region 318A. As described herein, extension region 316A and extension region 318A may be formed as regions with different doping concentrations, different doping depths in the active region, and different dopant species (e.g., doping material) from doping region 316 and doping region 318, respectively. In some embodiments, extension region 316A and extension region 318A (along with extension region 318B and extension region 326A, described below) may be highly doped drain extensions (HDD). First FET 310 may have metallurgical channel length 315 in channel region 314 that is defined as the length between extension region 316A and extension region 318A.

Turning to second FET 320, the second FET includes gate material 322 in gate region 306 above channel region 324 in active region 304 with the gate material surrounded by gate spacer 323 above substrate 302. Channel region 324 of second FET 320 is a region formed between doping region 318 on a first side of the channel region and doping region 326 on a second side of the channel region. In certain embodiments, doping region 318 is a drain region for second FET 320 and doping region 326 is a source region for the second FET. In some embodiments, doping region 318 is a shared doping region with the doping region shared between first FET 310 and second FET 320. For instance, doping region 318 may be a source region for first FET 310 that is shared as a drain region for second FET 320.

In various embodiments, contact 330 may be formed to connect to doping region 316 and contact 332 may be formed to connect to doping region 326. Contact 330 and contact 332 may be implemented, along with contacts to gate material 312 and gate material 322, to provide operational connections for low noise amplification by LNA 300. In some embodiments, a silicide region (such as silicide region 1020, shown in FIGS. 10 and 11) is formed in doped regions 316, 318, and 326 before forming contact 330 and contact 332. In various embodiments, contacts 330, 332 and the contacts to gate material 312 and gate material 322 are made of tungsten or another conductive material. In certain embodiments, drain doping region 316 of first FET 310 is the drain of the stacked FET and thus coupled to a power supply node (e.g., VDD) of an LNA circuit. Source doping region 326 of second FET 320 may be the source of the stacked FET and coupled to a ground node of the LNA circuit.

As shown in FIG. 3, doping region 318 includes extension region 318B on the first side of channel region 324 and doping region 326 includes extension region 326A on the second side of the channel region. Metallurgical channel length 360 is the length of channel region 324 between extension region 318B and extension region 326A.

In the illustrated embodiment of FIG. 3, gate material 322 in second FET 320 is placed at pitch 350 relative to gate material 312 in first FET 310. In certain embodiments, pitch 350 is greater than pitch 150 (shown in FIG. 1 and which is a minimum pitch defined for transistor region 103 or transistor region 203). In some embodiments, pitch 350 may be a similar pitch to pitch 250, shown in FIG. 2.

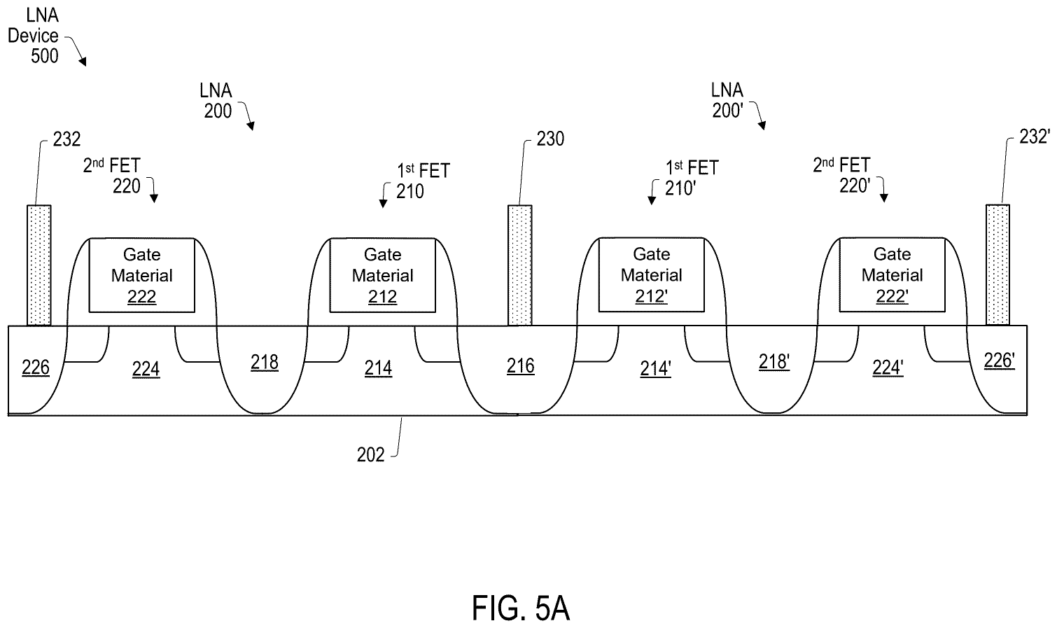

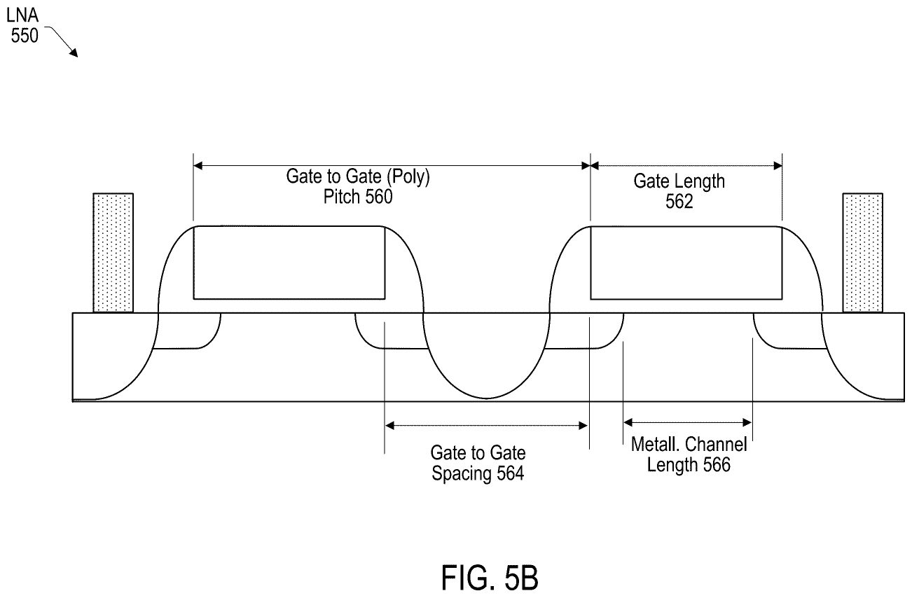

In certain embodiments, as shown in FIG. 3 and based on Equations (3) and (5) above, gate length 352 of gate material 322 may be increased relative to gate length 152 for gate material 122. Gate length 352 is increased relative to gate length 152 to reduce the gate resistance according to Equation (5) and lower the noise contribution from gate resistance according to Equation (2). Note that the gate length of gate material 312 may or may not be increased versus the gate length of gate material 112 as it has less impact on the signal-to-noise ratio. For instance, the gate length of gate material 312 may be equivalent to gate length 352 of gate material 322 or smaller (e.g., down towards gate length 152 or gate length 252 or the gate length of gate material 112 or gate material 212. With an increased gate pitch 350 for the increased gate length 352, the lateral diffusion of the gate extensions (e.g., extension regions 318B and 326A under gate material 322) may be increased and the metallurgical channel length may remain unchanged (e.g., metallurgical channel length 360 is substantially the same as metallurgical channel length 160). In various embodiments, doping region 326 is increased to the same size as doping region 318 due to an increased spacing of gate material 322 to a further gate positioned to the right of gate material 322 (similar to a multiple gate stacked FET, as shown in FIG. 5A). Contact 332 may then be a shared source contact. Alternatively, doping region 326 may be increased to same size as doping region 318 by defining it, via an optical mask, as wide as the spacing between gate material 312 and gate material 322. This increased lateral diffusion of extensions under gate material 322 increases the transconductance, gₘ, according to Equation (4) and the signal-to-noise ratio according to Equation (3). It may be possible to reduce the metallurgical channel length 360 to the value of the metallurgical channel length 260 if the gate length of gate material 312 is required to be equal to the gate length 352. Note, however, that channel length 359 corresponds to gate length 352 and thus the channel length is increased with the increase in the gate length. Accordingly, as channel length 359 increases while metallurgical channel length 360 remains the same, the difference between the channel length and the metallurgical channel length is greater for LNA 300 versus LNA 100. These factors work to reduce the gate resistance noise by use of a larger gate length 352 and increase the transconductance, gₘ, by an increased under-diffusion of dopants under gate material 322 to increase the signal-to-noise ratio for LNA 300 versus LNA 100 in contrast to the signal-to-noise ratio being increased for LNA 200. This solution may be preferable in technologies where the gate resistance is high and gate resistance noise dominates over the noise contribution from channel noise according to Equation (2).

The embodiments of a low noise stacked FET described in FIG. 2 and FIG. 3, in certain instances, share a common principle. In both embodiments, the ratio Lgₘ/Lgₚ of the metallurgical channel length Lgₘ (260 or 360) to the gate length Lgₚ (252 or 352) is reduced compared to all other transistors with a same gate length used in the technology or in the complete integrated circuit build of an overall device having the low noise stacked FETs as part of the overall device. In various embodiments, this principle may be stated in terms of the difference Lgₚ−Lgₘ of the gate length Lgₚ and the metallurgical channel length Lgₘ. In both embodiments, the difference Lgₚ−Lgₘ is increased compared to all other transistors with the same gate length used in the technology or in the complete integrated circuit build of an overall device having the low noise stacked FETs as part of the overall device.

It should be noted that, as discussed earlier, the amount of the increase in lateral diffusion of the extension regions under the gate materials may be controlled by forming first spacers (as part of spacer 313 and spacer 323) with a first width before forming the extension regions. Second spacers with second widths may be formed over the first spacers after forming the extension and before forming doping regions 316, 318, and 326 (e.g., the source and drain regions of the low noise stacked FET device that is electrically coupled, via contacts 330 and 332, to further parts of the LNA circuit). Accordingly, the increased lateral diffusion of the extension regions that corresponds to the increase in gate length may be controlled through the use of first and second spacers. The use of first and second spacers during fabrication is described further below with respect to the embodiments depicted in FIGS. 8 and 9.

In some embodiments, further improvements in the signal-to-noise ratio may be achieved by specific adjustment in the lengths of the extension regions of the doping regions (e.g., specifying lengths for extension region 218B and extension region 226A). Changes in doping concentrations may also affect the signal-to-noise ratio as well as the placement and doping of halo structures along the channel region to adjust the threshold voltage (Vth) and drain induced barrier lowering effect (DIBL) of the FET. Pitch between gates, gate length, and channel length may also be variables that can be adjusted and optimized to improve signal-to-noise ratio for the LNA devices described herein.

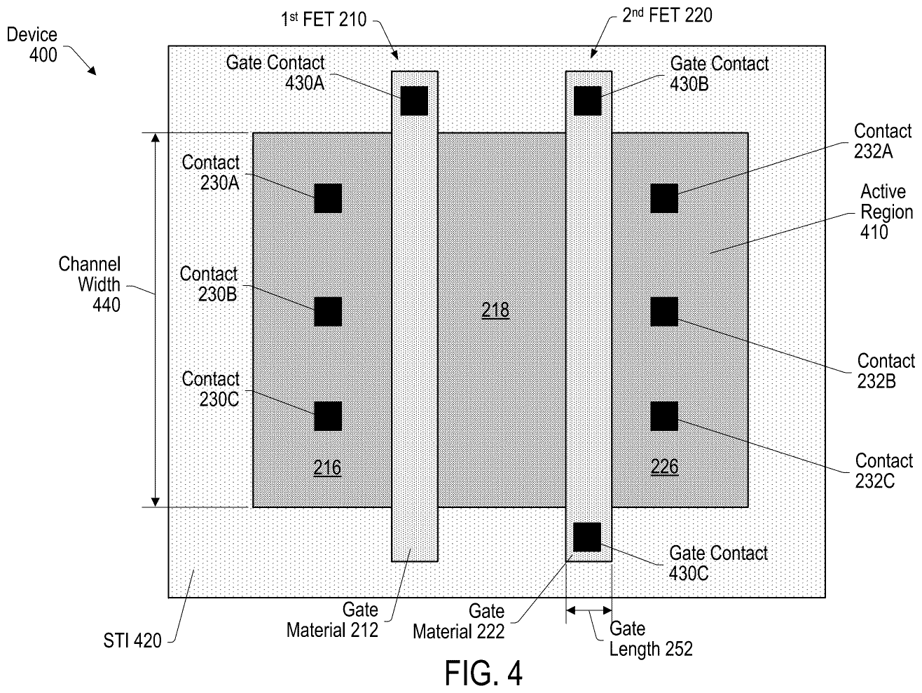

FIG. 4 is a top view representation of a low noise amplifier active device showing channel width per gate finger, according to some embodiments. It is noted that the top view representation in FIG. 4 shows the channel width per gate finger, which is not seen in the views of FIGS. 1-3. In the illustrated embodiment, LNA device 400 includes LNA 200 with active region 410. Active region 410 is surrounded by shallow trench isolation (STI) 420. STI 420 separates active region 410 from other active regions in device 400. STI 420 may be, for example, silicon oxide or another dielectric material.

In various embodiments, LNA 200 includes first FET 210 with gate material 212 and second FET 220 with gate material 222 (note that gate spacers 213/223 are not shown in FIG. 4 for simplicity in the drawing). Active region 410 includes doping region 216, doping region 218, and doping region 226 along with the doping extension regions and channel regions underneath gate materials 212/222 and the corresponding gate spacers (as shown in FIG. 2 but not shown in FIG. 4 for simplicity in the drawing). In various embodiments, gate contact 430A is coupled to gate material 212 and gate contacts 430B/430C are coupled to gate material 222. Other gate contacts may also be possible in some embodiments.

As shown in FIG. 4, gate material 212 and gate material 222 are “gate fingers” in device 400. Device 400 includes channel width 440 for active region 410, which gives the device a channel width per gate finger. In various embodiments, a channel width per gate finger is specified to give a best (e.g., optimum) signal-to-noise ratio for device 400. In some embodiments, as described for FIG. 5A below, multiple (gate) stacked FETs may be connected in parallel to increase the total channel width and increase the signal-to-noise ratio. For device 400, shown in FIG. 4, the noise of the stacked FET is dominated by second FET 220. Accordingly, the gate of second FET 220 is connected via gate contact 430B and gate contact 430C on both sides of gate material 222 to achieve a low gate resistance for device 400.

In various embodiments, channel width 440 of active region 410 allows multiple contacts to doping region 216 (e.g., drain region for first FET 210) and doping region 226 (e.g., source region for second FET 220) to be positioned in active region 410. For instance, in the illustrated embodiment, three contacts 230A-C are positioned on doping region 216 and three contacts 232A-C are positioned on doping region 226. The number of contacts may vary, for instance, based on channel width 440.

Various embodiments may also be contemplated that include multiple horizontally stacked FETs (e.g., an alternating and repeating pattern of multiple LNAs 200 and LNAs 200′) to increase channel width across a substrate. Increasing the channel width across the substrate by, for example, connecting individual stacked FETs electrically in parallel may increase the signal-to-noise ratio at the cost of some increased current consumption. FIG. 5A depicts a side-view representation of a low noise amplifier active device with two horizontally stacked FETs connected in parallel on a substrate, according to some embodiments. While FIG. 5A depicts two horizontally stacked FETs connected in parallel on a substrate, it should be understood that a device structure on the substrate may have any number of horizontally stacked FETs where the FETs share multiple source and drain regions along the horizontal dimension of the substrate between end source regions on the substrate.

In the illustrated embodiment, LNA device 500 includes LNA 200 and LNA 200′ (e.g., two gate fingers). LNA 200 includes first FET 210 and second FET 220 while LNA 200′ includes first FET 210′ and second FET 220′. It should be noted first FET 210 and second FET 220 in LNA 200 are reversed (e.g., mirrored) to allow LNA 200′ to have first FET 210′ sharing doping region 216 with first FET 210. LNA 200 and LNA 200′ have similar features with respect to gate materials 212/222, channel regions 214/224, doping regions 226/218, and extension regions. LNA 200 and LNA 200′ are “stacked (geometrically) together” and connected electrically in parallel by sharing drain doping region 216, as shown in FIG. 5A. A single shared contact—contact 230—may be connected to drain doping region 216 for use by both LNA 200 and LNA 200′ [note that there may be additional shared contacts not visible in the drawings]. With the shared drain doping region 216, LNA 200 and LNA 200′ are arranged in an alternating pattern and connected electrically in parallel.

In various embodiments, the alternating pattern of LNA 200 and LNA 200′ may be repeated N times to provide a 2×N times larger combined channel width across a substrate (e.g., substrate 202) compared to a single low noise stacked FET (e.g., either LNA 200 or LNA 200′ individually). The increase in total channel width is achieved by electrically connecting the LNAs in parallel. It may be noted that for an LNA circuit utilizing LNA devices 200 or 300 with an increased total channel width according to the structure of LNA device 500 in FIG. 5A, all the drain regions may be connected in parallel via metal wiring and all source regions may be connected in parallel via another metal wiring separated from the drain metal wiring. Further, gate material 212 and gate material 212′ of first FET 210 and first FET 210′, respectively, may be connected together in parallel by a first metal wiring while gate material 222 and gate material 222′ of second FET 220 and second FET 220′, respectively, are connected together in parallel by a second metal wiring separate from the first metal wiring. It should be noted that the parallel connected stacked FETs share the same gate length electrically-wise although geometrically-wise it may appear that gate lengths are added together. The electrical effect, however, contributes to the increase in signal-to-noise ratio.

The alternating pattern of FIG. 5A to increase the total channel width for the LNA active devices may be useful in certain instances for improving the signal-to-noise ratio. For instance, the signal amplitudes add in phase and lead to N² times the signal power while the noise power increases with N only, thus giving an improvement in signal-to-noise by N²/N=N. Accordingly, increasing the total channel width by increasing the channel width per “gate finger” (e.g., channel width 440 per LNA 200 or LNA 200′ in FIG. 4) may not be feasible for a low noise stacked FET as the gate resistance usually increases with a larger channel width per gate finger. In some embodiments, a specific channel width per gate finger is fixed by the constraint to achieve the highest signal-to-noise ratio. Accordingly, improving the signal-to-noise ratio may further require increasing the total channel width by connecting several low noise stacked FETs (e.g., LNA 200, 300, or 400) electrically in parallel (such as in LNA device 500) at the cost of increased current consumption.

Turning back to FIG. 2 (with applicability to FIGS. 3-5), two biasing schemes for the gate voltage of first FET 210 with respect to the ground node voltage (e.g., “GND”) of the LNA circuit may be contemplated. In a first contemplated embodiment, the gate voltage of gate 212 of first FET 210 is coupled (e.g., electrically connected) to the power supply voltage node (e.g., VDD) of the LNA circuit. In a second contemplated embodiment, the gate voltage of gate 212 of first FET 210 is biased at a voltage (e.g., a bias voltage) different from the power supply voltage. The bias voltage may be used to optimize the drain to the source voltage of second FET 220 that has the reduced metallurgical channel length to optimize the signal-to-noise ratio along with any other important device requirements. By the selection of the bias voltage different from the power supply voltage, the performance of the low noise stacked FET may be optimized. It should be noted that the drain to source voltage for second FET 220 and the drain to source voltage for first FET 210 are smaller than the power supply voltage (VDD), which allows a smaller metallurgical channel length for the low noise stacked FET. This smaller metallurgical channel length is not possible for a single FET where a reduced metallurgical channel length for a minimum gate length and a drain to source voltage equals to the power supply voltage leads to detrimental short channel effects and reliability concerns. In various embodiments, the bias voltage for gate 222 of second FET 220 is determined by optimizing the signal-to-noise ratio, the current consumption, and the signal amplification gain of the low noise stacked FET.

In certain embodiments of the present disclosure, a (low noise) stacked FET described herein has an increased poly pitch with a minimum gate length where the metallurgical channel length is shorter by, for example, 0.1 nm, 0.2 nm, 0.3 nm, 0.4 nm, 0.5 nm, 0.6 nm, 0.7 nm, 0.8 nm, 0.9 nm, 1 nm, 1.1 nm-2.9 nm, 3 nm, 4 nm, 5 nm, 6 nm, 7 nm, 8 nm, 9 nm or 10 nm compared to other FET with a minimum poly pitch and minimum gate length. In further embodiments of the present disclosure, a (low noise) stacked FET described herein has an increased poly pitch with a gate length above the minimum gate length where the metallurgical channel length is shorter by, for example, 0.1 nm, 0.2 nm, 0.3 nm, 0.4 nm, 0.5 nm, 0.6 nm, 0.7 nm, 0.8 nm, 0.9 nm, 1 nm, 1.1 nm-2.9 nm, 3 nm, 4 nm, 5 nm, 6 nm, 7 nm, 8 nm, 9 nm or 1 Onm compared to other FET with a minimum poly pitch and the same (or similar) gate length. In yet further embodiments of the present disclosure, a (low noise) stacked FET described herein has an increased poly pitch with a gate length above the minimum gate length where the metallurgical channel length is shorter by, for example, 0.1 nm, 0.2 nm, 0.3 nm, 0.4 nm, 0.5 nm, 0.6 nm, 0.7 nm, 0.8 nm, 0.9 nm, 1 nm, 1.1 nm-2.9 nm, 3 nm, 4 nm, 5 nm, 6 nm, 7 nm, 8 nm, 9 nm or 10 nm compared to other FET with the same poly pitch and the same gate length.

The above-described comparisons of dimensions, as indicated, are provided as examples of differences in the metallurgical channel length. According to present disclosure, there may be various combinations of gate (poly) pitch, gate length, and metallurgical channel length for the embodiments described herein that are different from other conventional (e.g., normal) FETs that may be available for the described technology. TABLE I (shown below) provides a schematic comparison of geometrical dimensions of the low noise stacked FETs capable according to the disclosed embodiments against geometrical dimensions of conventional FETs. FIG. 5B depicts a cross-sectional side-view representation of an FET showing the geometrical dimensions referred to in Table I for LNA 550.

TABLE I

| Normal multi gate finger FETs | | | | Low noise stacked FETs | | | |
|---|---|---|---|---|---|---|---|
| including stacked FETs | | | | of present disclosure | | | |
| Gate2Gate | | | Metall. | Gate2Gate | | | Metall. |
| (Poly) | Gate | Gate2Gate | Channel | (Poly) | Gate | Gate2Gate | Channel |
| Pitch | Length | Spacing | Length | Pitch | Length | Spacing | Length |
| 560 | 562 | 564 | 566 | 560 | 562 | 564 | 566 |
| Min | Min | Min | Min | >Min | Min | >Min | <Min |
| Min + X | Min + X | Min | Min + X | >Min + X | Min + X | >Min | <Min + X |
| Min + X | Min + X | Min | Min + X | >Min + X | Min + X | >Min | Min |
| Min + X | Min + X | Min | Min + X | >Min + X | Min + X | >Min | <Min |
| >Min | Min | >Min | Min | >Min | Min | >Min | <Min |
| Min + X + Y | Min + X | Min + Y | Min + X | Min + X + Y | Min + X | Min + Y | <Min + X |
| Min + X + Y | Min + X | Min + Y | Min + X | Min + X + Y | Min + X | Min + Y | Min |
| Min + X + Y | Min + X | Min + Y | Min + X | Min + X + Y | Min + X | Min + Y | <Min |

In TABLE I:
Min: minimum dimension for each of the geometrical quantity indicated used in the technology (for digital (normal) FETs)
X: gate length adder to minimum gate length
Y: Gate to Gate Spacing adder to minimum gate to gate spacing
>Min: Larger than minimum
<Min: Smaller than minimum

### Example Signal Processing System

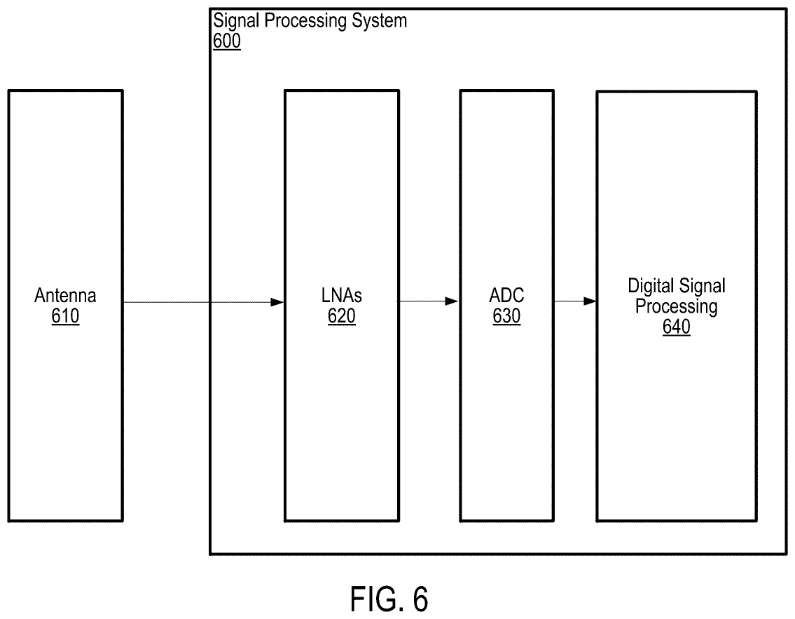

Turning next to FIG. 6, a block diagram of one embodiment of a signal processing system 600 that may implement the low noise amplifiers (LNA) described herein is shown. In the illustrated embodiment, signal processing system 600 is coupled to antenna 610. Antenna 610 may include one or more antennas configured to transmit/receive wireless signals such as radio frequency (RF) signals, millimeter wave signals, or sub-Terahertz wave signals. Antenna 610 may be, for example, an antenna associated with a wireless or mobile device. In some embodiments, antenna 610 may be an antenna array with many individual antennas for providing beamforming capability to steer an electromagnetic radiation receive pattern towards a transmitting/receiving base station or a transmitter of a mobile or wireless network. In some embodiments, one LNA may be connected to each antenna of the antenna array. In some embodiments, two LNA may be connected to each antenna to support sensitive receiving of circular polarized waves. In various embodiments, signal processing system 600 may be part of a modem.

Signal processing system 600 includes LNAs 620, ADC 630, and digital signal processing 640. In various embodiments, signals from antenna 610 are received by LNAs 620. LNAs 620 may amplify the signals in the analog domain with the improved signal-to-noise ratios described herein. If the frequency of the signal carrier is much higher than the frequency bandwidth of the signal, signal processing system 600 may include a frequency down conversion device such as a mixer (not shown). The frequency down conversion can happen in more than one step requiring more than one mixer. ADC (analog-to-digital converter) 630 may convert the amplified (and possibly down converted) analog signals to digital signals that are then processed by digital signal processing 640. Various different signal processing schemes may be contemplated based on the example block diagram shown in FIG. 6.

### Example Manufacturing Method

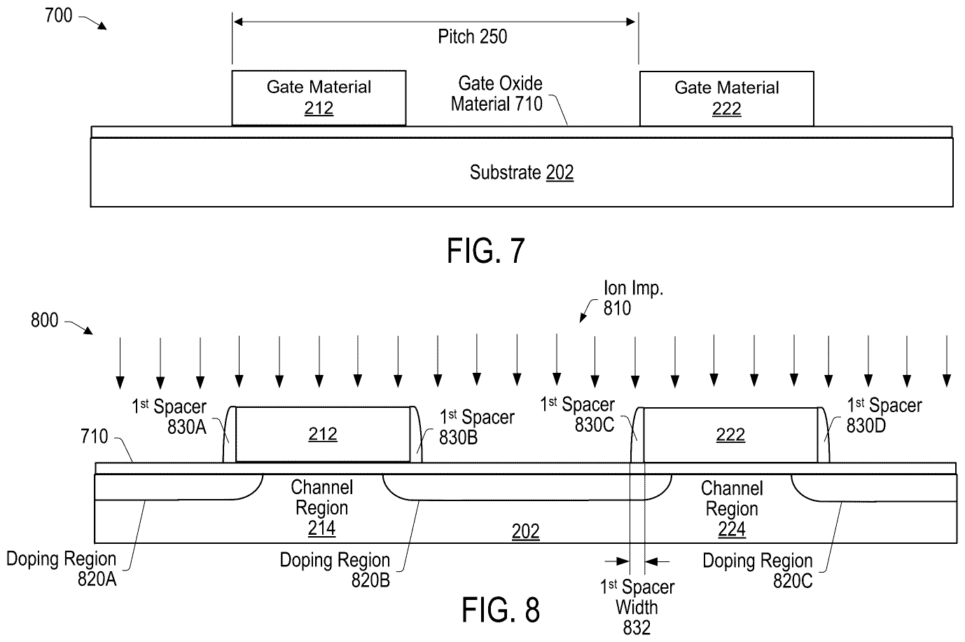

FIGS. 7-11 depict cross-sectional side-view representations of various possible steps in an exemplary embodiment of a method for manufacturing LNA 200 (or LNA 300) with horizontally stacked FETs 210 and 220 (or FETs 310 and 320) (as shown in FIGS. 2-5). Note that FIGS. 7-11 are directed to the embodiment of LNA 200 and shown along the same cross-sectional view of FIG. 2 for showing results of manufacturing (e.g., process) steps to form LNA 200 on substrate 202. While the cross-sectional side-view representations in FIGS. 7-11 illustrate possible structural results of manufacturing steps for a low noise amplifier with horizontally stacked FETs being formed on a substrate, it should be understood that similar manufacturing steps may be applied to any variations described herein. Furthermore, it is noted that FIGS. 7-11 depict cross-sectional side-view representations of intermediate structural results (e.g., structural end results for layers in a layer-by-layer manufacturing process) of manufacturing steps involved in forming a LNA with horizontally stacked FETs.

In various embodiments, one or more semiconductor manufacturing processing steps are implemented to form the intermediate structural results or structural end results depicted in FIGS. 7-11. Examples of semiconductor manufacturing processing steps include, but are not limited to, wafer fabrication, etching (e.g., material removal), photolithography processing, deposition (e.g., material deposition), planarization (e.g., chemical mechanical planarization/polishing (CMP)), doping by ion implantation or plasma doping, annealing, packaging, and packaging test (e.g., end product testing). Etching may include any of various etching techniques such as, but not limited to, wet etching, dry etching, plasma etching, and laser etching. Annealing may include thermal anneal or laser anneal to activate and induce dopant diffusion or induce formation of silicide. Photolithography processing may include steps for mask deposition, irradiation (e.g., patterning), pattern transfer (including any related etching, deposition, or ion implantation steps), and mask removal (if necessary). Material deposition may include deposition processes such as, but not limited to, physical deposition, chemical deposition, chemical vapor deposition, atomic layer deposition, evaporation, diffusion, spin coating, and electron beam deposition.

Any of the various semiconductor manufacturing processing steps mentioned above along with any related semiconductor manufacturing processing steps not explicitly disclosed may be implemented to arrive at the structures depicted in FIGS. 7-11 with the understanding that those skilled in the art would be able to determine a set of appropriate semiconductor manufacturing processing steps for implementing the depicted structures based on the present disclosure. Additionally, at some points throughout the present disclosure, semiconductor manufacturing processing steps may be explicitly recited in relation to specific structures. In such instances, it is understood that variations beyond the explicitly recited semiconductor manufacturing processing steps may be possible as known to those skilled in the art. Thus, while FIGS. 7-11 depict one exemplary embodiment for step-by-step manufacturing of devices described herein, additional embodiments for manufacturing devices described herein may be contemplated with modifications or alternatives that fall within the spirit or scope of the present disclosure where such modification or alternatives may include variations on the disclosed semiconductor manufacturing processing steps.

FIG. 7 is a cross-sectional side-view representation of beginning manufacturing steps of an LNA (low noise amplifier) with horizontally stacked FETs on a substrate, according to some embodiments. In the illustrated embodiments, process 700 includes the formation of gate oxide material 710 on top of substrate 202 and then the formation of gate material 212 and gate material 222 on the gate oxide material. In some embodiments, gate material 212/222 may be pre-doped (e.g., in the instance of silicide polysilicon gates for n-type doping for NFETs) to reduce the gate resistance. Gate oxide material 710 may be, for example, a thin layer of silicon dioxide or another oxide covering the top surface of substrate 202. In certain embodiments, gate oxide material 710 is formed by thermal oxidation of the top surface of substrate 202. In some embodiments, gate oxide 710 is formed by first forming a thermal grown interface oxide layer on the substrate and then on top of the thermal grown layer, depositing a high-k dielectric material with a high dielectric constant (e.g., a dielectric constant at least as large as the dielectric constant of silicon oxide or larger) by molecular chemical vapor deposition or atomic layer deposition. The high-k dielectric material may be, for example, a Hafnium-based oxide.

Gate material 212 and gate material 222 may include, but not be limited to, polysilicon, metal, silicides, or combinations thereof. In instances of silicided polysilicon gates, after gate material deposition the gate material may be pre-doped to reduce the gate resistance. Gate material 212 and gate material 222 may include the same gate material or be different gate materials (e.g., different gate materials for tuning the threshold voltage of the stacked FET or reducing the gate resistance of the second FET 220). Gate material 212 and gate material 222 may be formed in the same processing steps (e.g., when same material) or in different processing steps (e.g., when different materials). In some embodiments, gate material 212 and gate material 222 are formed by deposition of the gate material across the surface and then removal of unwanted areas of gate material through patterning and etching. A selective deposition process may also be implemented. In certain embodiments, as shown in FIG. 7, gate material 212 and gate material 222 are formed with pitch 250 between the gate material. Pitch 250, as described herein, may be a pitch greater than a minimum pitch defined for a transistor region on substrate 202.

FIG. 8 is a cross-sectional side-view representation of a next manufacturing step of an LNA (low noise amplifier) with horizontally stacked FETs on a substrate, according to some embodiments. In the illustrated embodiment, process 800 includes forming first spacers 830A-D with first spacer width 832 and then ion implantation 810 exposure of the device. In some embodiments, first spacers 830A-D (and second spacers 930A-D, shown in FIG. 9) are formed by depositing the material of the spacers across the device and then etching back the material to leave the spacers along the sidewalls of gate material 212 and gate material 222, as shown in FIG. 8. First spacers 830A-D may be formed, for example, from a nitride, an oxide, or another electrically insulating material. In some embodiments, ion implantation 810 may include exposure to arsenic (As) or antimony (Sb) ions or other suitable ions.

In certain embodiments, as shown in FIG. 8, ion implantation 810 forms doping regions 820A-C where gate oxide material 710 and substrate 202 are uncovered by gate material 212 and gate material 222 (e.g., areas of the substrate exposed outside the gate materials). Formation of doping regions 820A-C forms channel region 214 and channel region 224 under gate material 212 and gate material 222, respectively. Channel region 214, as described herein, has a metallurgical channel length defined by the distance between doping region 820A and doping region 820B (after thermal anneal) while channel region 224 has a metallurgical channel length defined by the distance between doping region 820B and doping region 820C (after thermal anneal). It should be noted that doping regions 820A-C have some later lateral diffusion under gate material 212 and gate material 222. The extent of the lateral diffusion of doping regions 820A-C depends on the amount by the timely duration and intensity (dosage) and angle of ion implantation 810, the thermal budget of a subsequent anneal step inducing dopant diffusion and the width of first spacers 830A-D. The extent of lateral diffusion may be controlled by controlling the number of dopants deposited (e.g., intensity of ion implantation 810), angle of the ion implantation, the dopant species (e.g., dopant material) with its diffusion constant, the available area where the dopants are introduced (e.g., the space or distance between spacer 830B and spacer 830C) and the width of the first spacers 830A-D.

After the ion implantation and formation of doping regions 820A-C, second spacers with a second width may be formed over gate spacers 830 around gate material 212 and gate material 222 to form the final gate spacers for the FET gates. FIG. 9 is a cross-sectional side-view representation of a manufacturing step to form second gate spacers for an LNA (low noise amplifier) with horizontally stacked FETs on a substrate, according to some embodiments. In the illustrated embodiment, process 900 includes forming second spacers 930A-D with second spacer width 932 over first spacers 830A-D around gate material 212 and gate material 222. Second spacers 930A-D may be formed, for example, from a silicon nitride, a silicon oxide, or another electrically insulating material. The material of the second spacers 930A-D may be different from the material of first spacers 830A-D. The first spacer first width 832 and second spacer second width 932 may be different or the same. In some embodiments, second spacers 930A-D are formed by depositing the material of the spacers across the device and then etching back the material to leave the spacers along the sidewalls of gate material 212 and gate material 222, as shown in FIG. 9. First spacers 830A-D and second spacers 930A-D combine together to form spacers 213 around gate material 212 and spacers 223 around gate material 222. For instance, first spacers 830A-B and second spacers 930A-B combine to form spacers 213 around gate material 212 and first spacers 830C-D and second spacers 930C-D combine to form spacers 223 around gate material 222.

FIG. 10 is a cross-sectional side-view representation of a next doping step for an LNA (low noise amplifier) with horizontally stacked FETs on a substrate, according to some embodiments. In the illustrated embodiment, process 1000 includes ion implantation 1010 exposure of the device to form additional doping regions 216, 218, 226 in substrate 202 where gate oxide material 710 and substrate 202 are uncovered by gate material 212, spacers 213, gate material 222, and spacers 223 (e.g., areas of the substrate exposed outside the gate materials and spacers). In some embodiments, ion implantation 1010 may include exposure to arsenic ions, phosphorus ions, or other suitable ions. In certain embodiments, ion implantation 1010 uses the same ions as ion implantation 810, described above. Embodiments may be contemplated, however, wherein ion implantation 1010 uses different implantation ions.

As shown in FIG. 10, ion implantation 1010 forms doping region 216 where doping region 820A has been exposed. After formation, doping region 216 connects to extension region 216A where the extension region is the remnant of doping region 820A. Similarly, doping region 218 is formed where doping region 820B has been exposed. Doping region 218 then connects to extension region 218A and extension region 218B, which are remnants of doping region 820B. Doping region 226 is formed where doping region 820C has been exposed. Doping region 226 connects to extension region 226A, which is a remnant of doping region 820C. After ion implantation 1010, a thermal anneal step may be implemented to activate the dopant. With the formation of doping regions 216, 218, and 226, the device now includes first FET 210 and second FET 220.

In some contemplated embodiments, process steps may be included for replacement of the gate material (e.g., a “gate last process” or “replacement gate process” is implemented). In such embodiments, gate material 212 and gate material 222 are removed from between spacers 213 and 223 and replaced with another gate material. In certain embodiments, the gate material in the replacement is a work function gate metal (such as TiN) that adjusts the threshold voltage of the FETs and above a gate conductor metal (e.g., aluminum) that lowers the gate resistance and on which a contact can be formed. Any other suitable metals or metal stacks, however, may be implemented for the gate material in the replacement.

In various embodiments, a metal is formed over the uncovered portions of doping regions 216, 218, 226 (e.g., regions not covered by spacers 213/223 or gate material 212/222). A rapid thermal anneal step may form silicide regions 1020, shown in FIG. 10, from the metal and the top of the doped silicon substrate. The metal may be selected from titanium (Ti), cobalt (Co), nickel (Ni), platinum (Pt), or a combination thereof. In some embodiments, the metal is also deposited over the gate material (such as polysilicon) and a silicide polysilicon gate is formed.

FIG. 11 is a cross-sectional side-view representation of a later manufacturing step for an LNA (low noise amplifier) with horizontally stacked FETs on a substrate, according to some embodiments. In the illustrated embodiment, process 1100 includes forming contact 230 to silicide region 1020 in doping region 216 and contact 232 to silicide region 1020 in doping region 226. In addition, contact may be formed on gates to gate material 212 and gate material 222 (such as gate contacts 430A-C, shown in FIG. 4) to provide operational connections for low noise amplification by LNA 200. Contact 230 and contact 232 may be formed by a deposition process for conductive material (e.g., tungsten (W) or another metal) in a specific pattern. For example, in some embodiments, contact 230 and contact 232 may be formed through a dielectric material (not shown) that encloses LNA 200 on substrate 202. Accordingly, contact 230 and contact 232 may be contacts through the dielectric material formed by creating openings in the dielectric material and filling the openings with conductive material for the contacts. With the formation of contacts 230, 232, LNA 200 is formed with horizontally stacked FETS-first FET 210 and second FET 220. Additional processing steps may follow to compete the fabrication of the LNA device. For instance, additional steps for forming metal layers above first FET 210 and second FET 220 may follow process 1100 in order to fully form an LNA circuit for the device.

While the embodiments of the low noise stacked FET described above relate to a planar process, in some embodiments, the low noise stacked FET may be formed in a planar bulk CMOS process, a bulk FinFET CMOS process, a fully depleted silicon-on-insulator (FDSOI) process, or a partially depleted silicon-on-insulator (PDSOI) process.

### Example Computer System

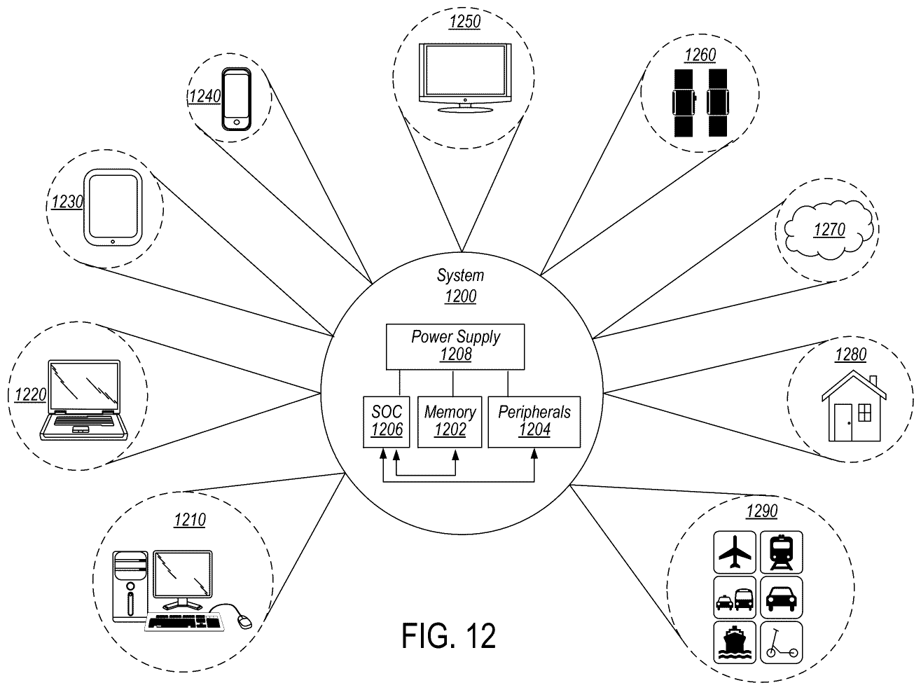

Turning next to FIG. 12, a block diagram of one embodiment of a system 1200 is shown that may incorporate and/or otherwise utilize the methods and mechanisms described herein. In the illustrated embodiment, the system 1200 includes at least one instance of a system on chip (SoC) 1206 which may include multiple types of processing units, such as a central processing unit (CPU), a graphics processing unit (GPU), or otherwise, a communication fabric, and interfaces to memories and input/output devices. In some embodiments, one or more processors in SoC 1206 includes multiple execution lanes and an instruction issue queue. In various embodiments, SoC 1206 is coupled to external memory 1202, peripherals 1204, and power supply 1208.

A power supply 1208 is also provided which supplies the supply voltages to SoC 1206 as well as one or more supply voltages to the memory 1202 and/or the peripherals 1204. In various embodiments, power supply 1208 represents a battery (e.g., a rechargeable battery in a smart phone, laptop or tablet computer, or other device). In certain embodiments, power supply 1208 includes a power management unit (PMU) that includes one or more DC/DC converters. In some embodiments, more than one instance of SoC 1206 is included (and more than one external memory 1202 is included as well).

The memory 1202 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 1204 include any desired circuitry, depending on the type of system 1200. For example, in one embodiment, peripherals 1204 includes devices for various types of wireless communication, such as Wi-Fi, Bluetooth, cellular (modem), global positioning system, satellite communications, etc. In some embodiments, the peripherals 1204 also include additional storage, including RAM storage, solid state storage, or disk storage. The peripherals 1204 include user interface devices such as a display screen, including touch display screens or multitouch display screens, keyboard or other input devices, microphones, speakers, etc.

As illustrated, system 1200 is shown to have application in a wide range of areas. For example, system 1200 may be utilized as part of the chips, circuitry, components, etc., of a desktop computer 1210, laptop computer 1220, tablet computer 1230, cellular or mobile phone 1240, or television 1250 (or set-top box coupled to a television). Also illustrated is a smartwatch and health monitoring device 1260. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 1200 may further be used as part of a cloud-based service(s) 1270. For example, the previously mentioned devices, and/or other devices, may access computing resources in the cloud (i.e., remotely located hardware and/or software resources). Still further, system 1200 may be utilized in one or more devices of a home 1280 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 12 is the application of system 1200 to various modes of transportation 1290. For example, system 1200 may be used in the control and/or entertainment systems of aircraft, trains, buses, cars for hire, private automobiles, waterborne vessels from private boats to cruise liners, scooters (for rent or owned), and so on. In various cases, system 1200 may be used to provide automated guidance (e.g., self-driving vehicles), general systems control, and otherwise. These any many other embodiments are possible and are contemplated. It is noted that the devices and applications illustrated in FIG. 12 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design (such as the described LNA circuit) along with synthesized circuitry. The integrated circuits may include transistors and other circuit elements (e.g., passive elements such as capacitors, resistors, inductors, coils, transformers, etc.) and interconnect between the transistors and circuit elements (such as the described LNA circuit). Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. A device, comprising:
a low-noise amplifier circuit located in a transistor region of an integrated circuit structure, the transistor region including a gate region positioned vertically above an active region of a substrate, the low-noise amplifier circuit comprising:
a first field-effect transistor (FET) having a first gate material in the gate region positioned vertically above a first portion of the active region, wherein the first FET includes a first channel region in the first portion of the active region vertically below the first gate material, wherein the first channel region is formed horizontally between a first doping region on a first side of the first channel region and a second doping region on a second side of the first channel region; and
a second field-effect transistor (FET) stacked horizontally adjacent to the first FET on the substrate, wherein the second FET has a second gate material in the gate region positioned vertically above a second portion of the active region, wherein the second FET includes a second channel region in the second portion of the active region vertically below the second gate material, wherein the second channel region is formed horizontally between the second doping region on a first side of the second channel region and a third doping region on a second side of the second channel region, and wherein the second channel region has a metallurgical channel length in a first horizontal direction defined as a horizontal distance between the second doping region and the third doping region;
wherein a pitch between the first gate material and the second gate material is greater than a minimum pitch defined for the transistor region, and wherein the metallurgical channel length for the second channel region is less than a metallurgical channel length when the pitch between the first gate material and the second gate material is set at the minimum pitch defined for the transistor region.

2. The device of claim 1, wherein the second gate material has a gate length in the first horizontal direction that is approximately the same as a gate length for the second gate material when the pitch between the first gate material and the second gate material is set at the minimum pitch defined for the transistor region.

3. The device of claim 1, wherein the second doping region is a source/drain region shared by the first FET and the second FET.

4. The device of claim 1, wherein the first doping region is a drain region for the first FET and the third doping region is a source region for the second FET.

5. The device of claim 1, wherein the horizontal distance between the second doping region and the third doping region is a distance between portions of the second doping region and the third doping region that are horizontally closest.

6. The device of claim 1, wherein the first doping region includes an extension region that extends horizontally with at least a portion of the extension region being vertically below the first gate material.

7. The device of claim 1, wherein the second doping region includes a first extension region that extends horizontally with at least a portion of the first extension region being vertically below the first gate material and a second extension region that extends horizontally with at least a portion of the second extension region being vertically below the second gate material.

8. The device of claim 7, wherein the third doping region includes a third extension region that extends horizontally with at least a portion of the third extension region being vertically below the second gate material.

9. The device of claim 8, wherein the horizontal distance between the second doping region and the third doping region is a distance horizontally between the second extension region and the third extension region.

10. The device of claim 1, wherein the pitch between the first gate material and the second gate material is a distance between an edge of the first gate material above the first side of the first channel region and an edge of the second gate material above the first side of the second channel region.

11. A device, comprising:
a low-noise amplifier circuit located in a transistor region of an integrated circuit structure, the transistor region including a gate region positioned above an active region of a substrate in a vertical dimension, the low-noise amplifier circuit comprising:
a first field-effect transistor (FET) having a first gate material in the gate region positioned above a first portion of the active region in the vertical dimension, wherein the first FET includes a first channel region in the first portion of the active region below the first gate material in the vertical dimension, wherein the first channel region is formed between a first drain region on a first side of the first channel region in a horizontal dimension and a first source region on a second side of the first channel region in the horizontal dimension; and
a second field-effect transistor (FET) electrically coupled in series to the first FET, wherein the second FET has a second gate material in the gate region positioned above a second portion of the active region in the vertical dimension, wherein the second FET includes a second channel region in the second portion of the active region below the second gate material in the vertical dimension, wherein the second channel region is formed between a second drain region on a first side of the second channel region in the horizontal dimension and a second source region on a second side of the second channel region in the horizontal dimension, and wherein the second channel region has a metallurgical channel length in a first direction of the horizontal dimension defined as a distance between the second drain region and the second source region in the horizontal dimension;
wherein a pitch between the first gate material and the second gate material is greater than a minimum pitch defined for the transistor region, and wherein the metallurgical channel length for the second channel region is less than a metallurgical channel length when the pitch between the first gate material and the second gate material is set at the minimum pitch defined for the transistor region.

12. The device of claim 11, wherein the first source region and the second drain region are a single doping region shared by the first FET and the second FET.

13. The device of claim 11, wherein the distance in the horizontal dimension between the second drain region and the second source region is a distance between portions of the second drain region and the second source region that are closest together in the horizontal dimension.

14. The device of claim 11, wherein the first drain region and the first source region include extension regions that extend in the horizontal dimension with at least portions of the extension regions being below the first gate material in the vertical dimension.

15. The device of claim 11, wherein the second drain region and the second source region include extension regions that extend in the horizontal dimension with at least portions of the extension regions being below the second gate material in the vertical dimension.

16. The device of claim 15, wherein the distance in the horizontal dimension between the second drain region and the second source region is a distance in the horizontal dimension between the extension region of the second drain region and the extension region of the second source region.

17. A system, comprising:
one or more antennas configured to receive an RF (radio frequency) signal;
one or more low-noise amplifier circuits formed on a substrate, wherein the low-noise amplifier circuits are configured to amplify the RF signal, at least one low-noise amplifier circuit comprising:
a first field-effect transistor (FET) having a first gate material in a gate region positioned vertically above a first portion of an active region of the substrate, wherein the first FET includes a first channel region in the first portion of the active region vertically below the first gate material, the first channel region being formed horizontally between a first doping region on a first side of the first channel region and a second doping region on a second side of the first channel region; and
a second field-effect transistor (FET) having a second gate material in the gate region positioned vertically above a second portion of the active region of the substrate, wherein the second FET includes a second channel region in the second portion of the active region vertically below the second gate material, the second channel region being formed horizontally between the second doping region on a first side of the second channel region and a third doping region on a second side of the second channel region, and wherein the second channel region has a metallurgical channel length in a first horizontal direction defined as a horizontal distance between the second doping region and the third doping region;
wherein a pitch between the first gate material and the second gate material is greater than a minimum pitch defined for a transistor region in the at least one low-noise amplifier circuit, and wherein the metallurgical channel length for the second channel region is less than a metallurgical channel length when the pitch between the first gate material and the second gate material is set at the minimum pitch defined for the transistor region;
one or more analog-to-digital conversion circuits configured to convert the RF signal to a digital signal; and
one or more digital signal processing circuits configured to process the digital signal.

18. The system of claim 17, wherein the second doping region is a source/drain region shared by the first FET and the second FET, the first FET and the second FET being electrically coupled in series.

19. The system of claim 17, wherein the second gate material has a gate length in the first horizontal direction that is approximately the same as a gate length for the second gate material when the pitch between the first gate material and the second gate material is set at the minimum pitch defined for the transistor region.

20. The system of claim 17, wherein the system is located on a mobile device.
